(19) United States
(12) Patent Application Publication
(10) Pub. No.: US 2008/0101450 A1
(43) Pub. Date: May 1, 2008

(54) Second order continuous time linear equalizer

(76) Inventors: Zuoguo Wu, Santa Clara, CA (US); Peng Zou, Northborough, MA (US); Fenardi Thenus, Portland, OR (US)

Correspondence Address: BUCKLEY, MASCHOFF & TALWALKAR LLC, 50 LOCUST AVENUE, NEW CANAAN, CT, 06840, US

(21) Appl. No.: 11/586,920

(22) Filed: Oct. 26, 2006

(51) Int. Cl. H03K 5/159

(52) U.S. Cl. 375/232

(57) ABSTRACT

According to some embodiments, a continuous time linear equalization circuit includes an input of a first stage to receive a differential input signal, and an output of the first stage to output a differential output signal. A transfer function between the input and the output exhibits two zeros and three poles in frequency domain, and the differential output signal is not fed back to the first stage.

### BACKGROUND

A conventional data receiver samples received data based on sampling clock signals. The sampling clock signals are typically synchronized with the received data such that the received data is sampled within a time period, or “data eye”, during which the data is valid. Data errors may occur if the data is sampled at the edges of or outside of the data eye.

A high speed data link may employ any of several techniques to ensure that received data is correctly sampled. Continuous time linear equalization (CTLE) is one technique commonly implemented in a data receiver. According to CTLE, the received data is passed through a system having a transfer function which peaks at desired frequencies.

FIGS. 1A and 1B illustrate conventional CTLE circuits. Each illustrated circuit exhibits one zero and two poles in the frequency domain. Circuit 100 achieves this characteristic by adding resistor and capacitor parallel degeneration to a conventional differential pair, while the circuit 150 adds capacitor degeneration and a second input differential pair. The introduced pole and zero locations are controlled by the resistor and capacitor values of circuit 100, and by the capacitor value and transconductance of the second input differential pair of circuit 150.

A higher-order system including additional zeros and/or poles may improve CTLE. However, conventional higher-order systems require multiple stages and feedback, thereby increasing circuit complexity and power dissipation.

### BRIEF DESCRIPTION OF THE DRAWINGS

FIGS. 1A and 1B are schematic diagrams of conventional CTLE circuits.

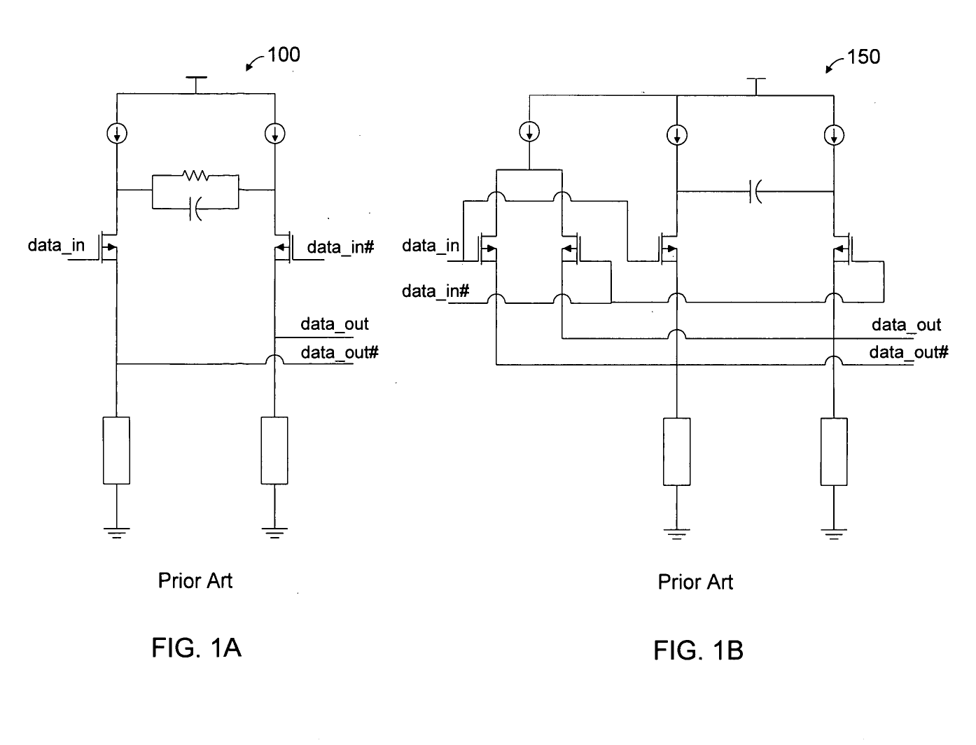

FIG. 2 is a schematic diagram of a circuit according to some embodiments.

FIG. 3 is a schematic diagram of a circuit according to some embodiments.

FIG. 4 is a schematic diagram of a circuit according to some embodiments.

FIG. 5 is a schematic diagram of a second stage for a circuit according to some embodiments.

FIG. 6 is a block diagram illustrating a portion of a receiver according to some embodiments.

FIG. 7 is a timing diagram illustrating relationships between a data signal and sampling clock signals according to some embodiments.

FIG. 8 is a block diagram of a system according to some embodiments.

### DETAILED DESCRIPTION

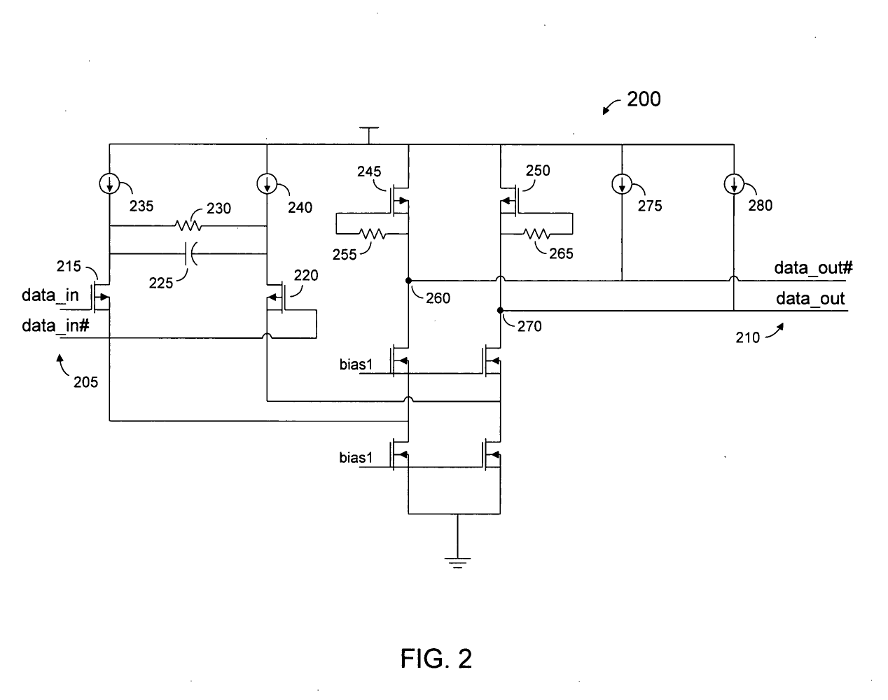

FIG. 2 is a schematic diagram of CTLE circuit 200 according to some embodiments. Circuit 200 includes input 205 of a first stage to receive a differential input signal. As is known in the art, the differential input signal consists of two signal portions (data_in, data_in#) and data is represented by a difference between the two signal portions.

Circuit 200 also includes output 210 of the first stage to output a differential output signal (data_out, data_out#). The differential output signal reflects the application of a transfer function to the differential input signal. The transfer function of circuit 200 exhibits two zeros and three poles in frequency domain. Also, the differential output signal is not fed back to the first stage.

Turning to the specific components of circuit 200, portion data_in of the differential input signal is received at a gate of p-type metal-oxide semiconductor (PMOS) transistor 215. Portion data_in#, in turn, is received by a gate of PMOS transistor 220. As shown, capacitive element 225 may comprise a capacitor and/or any other suitable capacitive element. A first node of capacitive element 225 is coupled to a drain of transistor 215 and a second node of capacitive element 225 is coupled to a drain of transistor 220.

Resistive element 230 may comprise any resistive element or elements that are or become known. A first node of resistive element 230 is coupled to the drain of transistor 215 and a second node of resistive element 230 is coupled to the drain of transistor 220. Also shown is current source 235, wherein, a first node of current source 235 is coupled to a supply voltage and a second node of current source 235 is coupled to the first node of resistive element 230. Similarly, a first node of current source 240 is coupled to a supply voltage and a second node of current source 240 is coupled to the second node of resistive element 230.

Circuit 200 also includes PMOS transistor 245 and PMOS transistor 250, drains of which are coupled to the supply power. Resistive element 255 includes a first node and a second node, with the first node of resistive element 255 being coupled to a gate of transistor 245 and the second node of resistive element 255 being coupled to a source of transistor 245. The second node is also coupled to output node 260 of the first stage, which outputs portion data_out# of the output differential signal.

Resistive element 265 also includes a first node and a second node. The first node of resistive element 265 is coupled to a gate of transistor 250 and the second node of resistive element 265 is coupled to a source of transistor 250 and to output node 270 of the first stage. Output node 270, as illustrated, is to output portion data_out of the output differential signal.

According to some embodiments, circuit 200 also includes current source 275 and current source 280. A first node of current source 275 is coupled to the supply power and a second node of current source 280 is coupled to output node 260. A first node of current source 280 is coupled to the supply power and a second node of current source 280 is coupled to output node 270. Current sources 275 and 280 may be controlled to control an operating point of circuit 200. Current sources 275 and 280 may also or alternatively be controlled to provide offset correction in order to move a center of the data eye to a desired voltage (e.g., 0V). Current sources 275 and 280 are optional in some embodiments.

According to some embodiments, the transfer function of circuit 200 comprises:

$$\frac{{g}_{m 1}}{{g}_{m 2} ( 1 + {g}_{m 1} \frac{{R}_{s}}{2} )} \frac{( 1 + {sR}_{s} {C}_{s} ) ( 1 + {sR}_{p} {C}_{g} )}{( 1 + s \frac{{R}_{s} {C}_{s}}{( 1 + {g}_{m 1} \frac{{R}_{s}}{2} )} ) ( 1 + s \frac{{C}_{g} + {C}_{L}}{{g}_{m 2}} + {s}^{2} \frac{{R}_{p} {C}_{g} {C}_{L}}{{g}_{m 2}} )} ,$$

where Rₛ is a resistance of resistive element 230, Rₚ is a resistance of resistive elements 245 and 250, gm₁ is a transconductance of the differential transistor pair 215/220, gm₂ is a transconductance of transistors 245 and 250, C_{g} is a total capacitance at the gate of transistors 245 and 250, and C_{L} is a total capacitance at output nodes 260 and 270. C_{L} may take into account loads of any circuits attached thereto.

According to some embodiments, at least one of resistive elements 230, 255 and 265 comprises a variable resistive element including but not limited to an active transistor circuit. The poles and zeroes of the above transfer function may be controlled by appropriate selection of the various components of circuit 200, and may also be controlled during operation by varying resistances of the resistive elements.

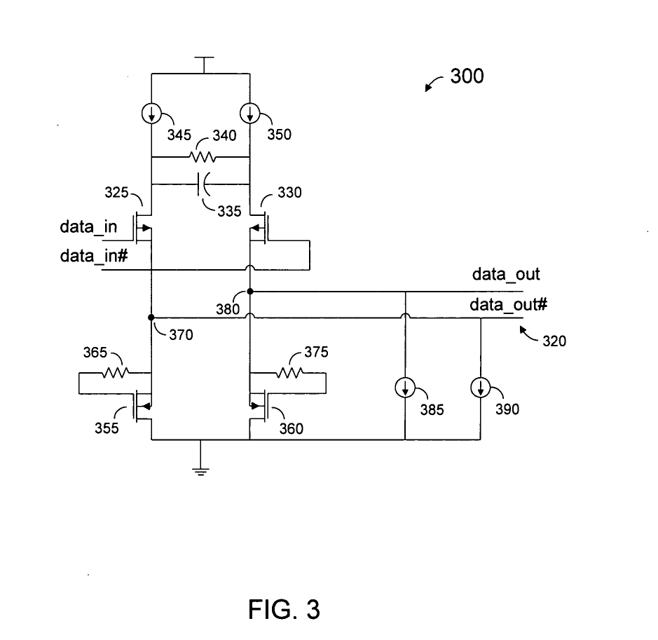

FIG. 3 is a schematic diagram of circuit 300 according to some embodiments. Circuit 300 includes input 310 of a first stage to receive a differential input signal (data_in, data_in#), and output 320 of the first stage to output a differential output signal (data_out, data_out#). As will be illustrated below, the transfer function of circuit 300 exhibits two zeros and three poles in frequency domain.

Portion data_in of the differential input signal is received at a gate of PMOS transistor 325. Portion data_in# of the differential input signal is received by a gate of PMOS transistor 330. A first node of capacitive element 335 is coupled to a drain of transistor 325 and a second node of capacitive element 335 is coupled to a drain of transistor 330. Capacitive element 335 may comprise any capacitive element or elements that are or become known.

A first node of resistive element 340 is coupled to the drain of transistor 325 and a second node of resistive element 340 is coupled to the drain of transistor 330. A first node of current source 345 is coupled to a supply voltage and a second node of current source 345 is coupled to the first node of resistive element 340. Similarly, a first node of current source 350 is coupled to the supply voltage and a second node of current source 350 is coupled to the second node of resistive element 340.

Circuit 200 also includes n-type metal-oxide semiconductor (NMOS) transistor 355 and NMOS transistor 360, drains of which are coupled to ground. Resistive element 365 includes a first node and a second node, with the first node of resistive element 365 being coupled to a gate of transistor 355 and the second node of resistive element 365 being coupled to a source of transistor 355. The second node is also coupled to output node 370 of the first stage, which outputs portion data_out# of the output differential signal.

Resistive element 375 also includes a first node and a second node. The first node of resistive element 375 is coupled to a gate of transistor 360 and the second node of resistive element 375 is coupled to a source of transistor 360 and to output node 380 of the first stage. Output node 380 is to output portion data_out of the output differential signal.

Circuit 300 also includes current source 385 and current source 390. A first node of current source 385 is coupled to output node 380 and a second node of current source 385 is coupled to ground. A first node of current source 390 is coupled to output node 370 and a second node of current source 390 is coupled to ground. Current sources 385 and 390 may be controlled to control an operating point of circuit 300 and/or to provide offset correction. Some embodiments of circuit 300 do not include current sources 385 and 390.

The transfer function of circuit 300 may be equal to:

$$\frac{{g}_{m 1}}{{g}_{m 2} ( 1 + {g}_{m 1} \frac{{R}_{s}}{2} )} \frac{( 1 + {sR}_{s} {C}_{s} ) ( 1 + {sR}_{p} {C}_{g} )}{( 1 + s \frac{{R}_{s} {C}_{s}}{( 1 + {g}_{m 1} \frac{{R}_{s}}{2} )} ) ( 1 + s \frac{{C}_{g} + {C}_{L}}{{g}_{m 2}} + {s}^{2} \frac{{R}_{p} {C}_{g} {C}_{L}}{{g}_{m 2}} )} ,$$

where Rₛ is a resistance of resistive element 340, Rₚ is a resistance of resistive elements 365 and 375, gm₁ is a transconductance of the differential transistor pair 325/330, gm₂ is a transconductance of transistors 355 and 360, C_{g} is a total capacitance at the gate of transistors 355 and 360, and C_{L} is a total capacitance at output nodes 370 and 380. C_{L} may take into account loads of any circuits attached thereto.

At least one of resistive elements 340, 365 and 375 may comprise a variable resistive element including but not limited to an active transistor circuit. The poles and zeroes of the above transfer function may be controlled by appropriate selection of the various components of circuit 300, and may also be controlled during operation by varying resistances of the resistive elements.

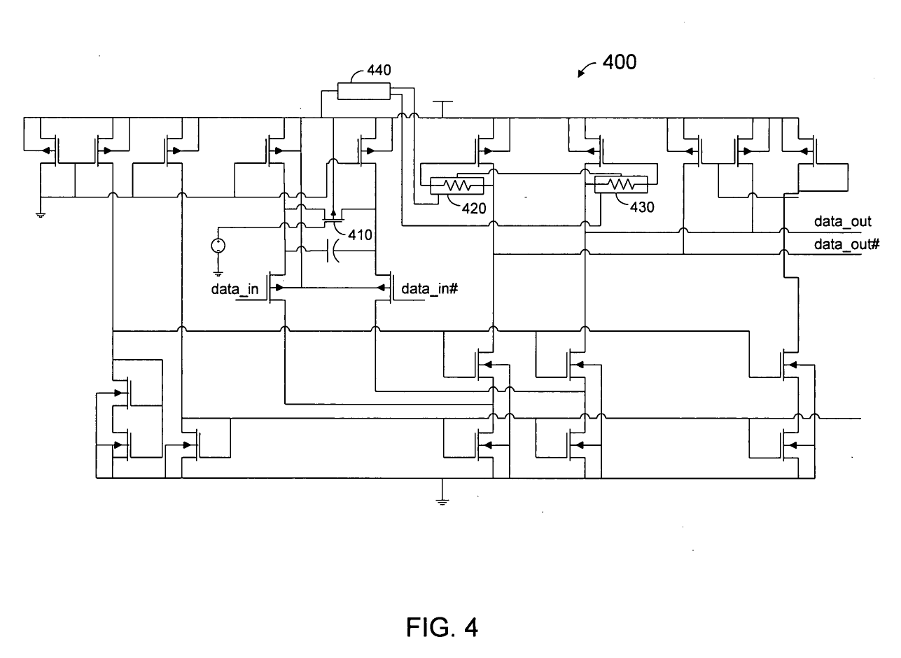

FIG. 4 illustrates circuit 400 according to some embodiments. Circuit 400 is an implementation of circuit 200 and therefore may exhibit each of the properties described above.

Circuit 400 employs current mirrors to implement current sources 235, 240, 275 and 280 of circuit 200. Moreover, DC-biased PMOS transistor 410 implements resistive element 230 and variable resistors 420 and 430 implement resistive elements 255 and 265, respectively. Control 440 operates to control resistances exhibited by variable active resistors 420 and 430.

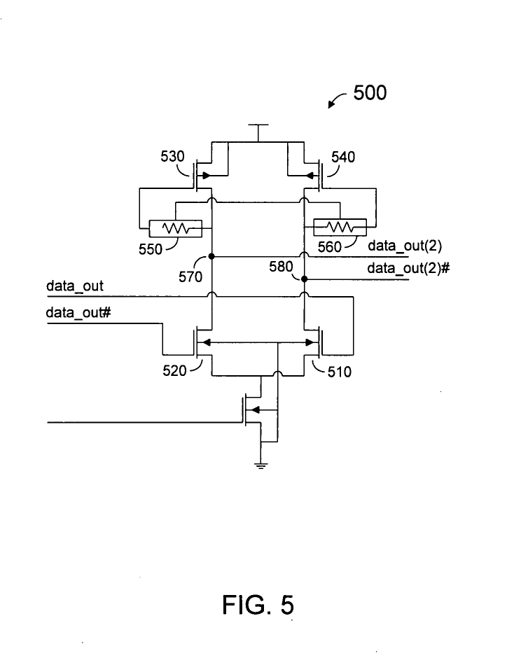

FIG. 5 is a schematic diagram of second stage circuit 500. Second stage circuit 500 may receive an output differential signal from any of circuits 200, 300 or 400, but embodiments are not limited thereto.

Portion data_out of the differential output signal is received at a gate of PMOS transistor 510. Portion data_out# is received by a gate of PMOS transistor 520. Circuit 500 also includes PMOS transistor 530 and PMOS transistor 540, sources of which are coupled to a supply power. Resistive element 550 includes a first node and a second node, with the first node of resistive element 550 being coupled to a gate of transistor 530 and the second node of resistive element 550 being coupled to a drain of transistor 530. The second node is also coupled to output node 570 of the first stage, which outputs portion data_out(2) of a second output differential signal.

Resistive element 560 also includes a first node and a second node. The first node of resistive element 560 is coupled to a gate of transistor 540 and the second node of resistive element 560 is coupled to a drain of transistor 540 and to output node 580 of the first stage. Output node 580, as illustrated, is to output portion data_out(2)# of the second output differential signal. Resistive elements 550 and 560 may be implemented by active transistor circuits controlled by a suitable control unit.

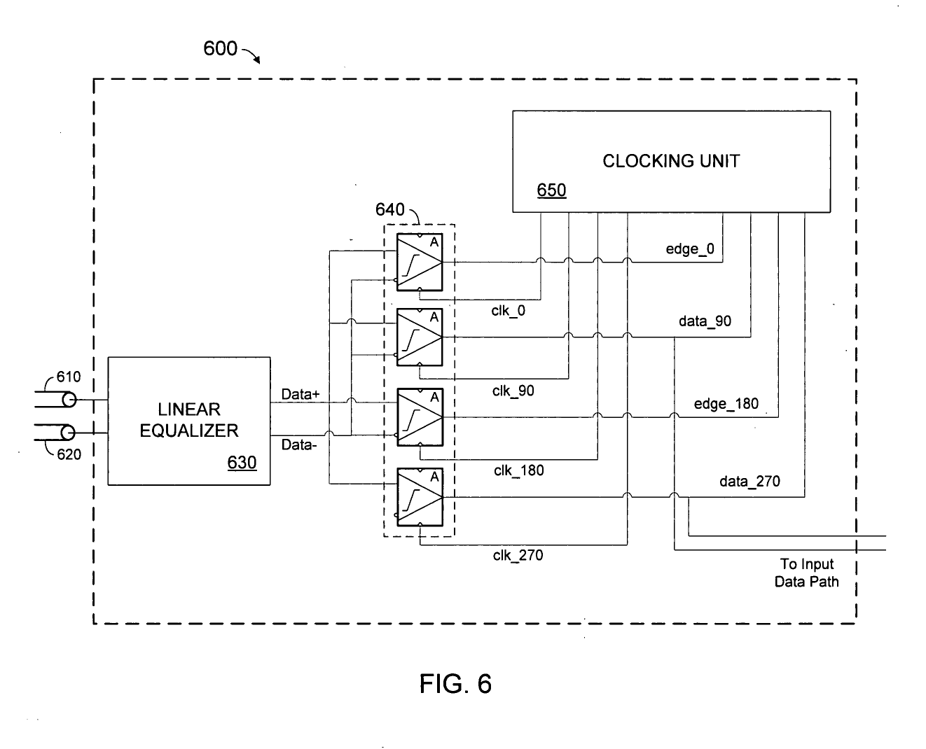

FIG. 6 is a block diagram of a portion of high-speed Input/Output (I/O) receiver 600 according to some embodiments. Receiver 600 may be an element of any system, including but not limited to a microprocessor, a chipset, a memory chip, and a line card. Receiver receives a differential data signal from interconnects 610 and 620. A typical I/O link may include many more interconnects than illustrated to carry data signals.

The differential data signal is received by linear equalizer 630. Linear equalizer 630 may be implemented by any suitable combination of circuits 200, 300, 400 and 500, but embodiments are not limited thereto. Linear equalizer 630 applies a transfer function to the received data and outputs a differential signal (Data+, Data−) to sampler block 640.

Sampler block 640 samples the differential signal based on clock signals received from clocking unit 650. As a result, sampler block 640 outputs signals edge_0 corresponding to a first edge of a first data eye, data_90 corresponding to a value sampled at a center of the first data eye, edge_180 corresponding to a first edge of a second data eye, and data_270 corresponding to a value sampled at a center of the second data eye. Each of these signals are fed back to clocking unit 650 so that clocking unit may control its output clock signals based thereon.

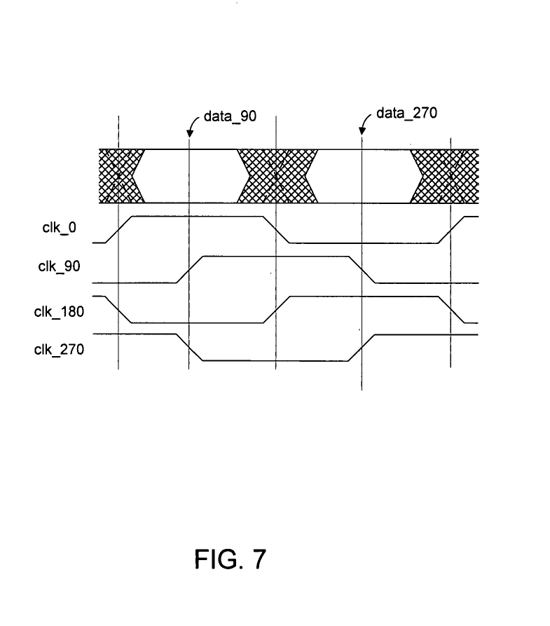

FIG. 7 illustrates relationships between the aforementioned signals and data eyes according to some embodiments. As shown, the clk_{—}0 and clk-180 signals transition between each data eye. Moreover, the transitions of the clk_{—}90 and clk_{—}270 signals occur at the center of the data eyes.

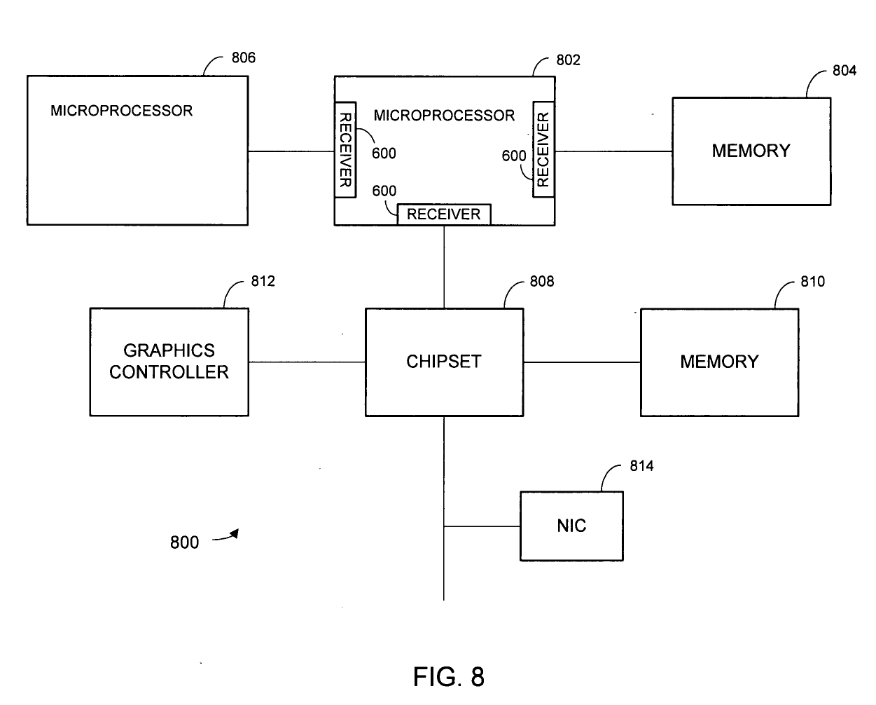

FIG. 8 illustrates a block diagram of system 800 according to some embodiments. System 800 includes microprocessor 802 comprising three instances of receiver 600 of FIG. 6. Microprocessor 802 may communicate directly with system memory 804 (e.g. Fully Buffered Dual In-line Memory Module) or with microprocessor 806 via receiver 600. System memory 804 may comprise any type of memory, including but not limited to Single Data Rate Random Access Memory and Double Data Rate Random Access Memory. Microprocessor 802 may also communicate with chipset 808 over a Configurable System Interconnect bus via receiver 600. Other off-die functional units, such as memory 810, graphics controller 812 and Network Interface Controller (NIC) 814, may communicate with microprocessor 802 via chipset 808.

The several embodiments described herein are solely for the purpose of illustration. Therefore, persons in the art will recognize from this description that other embodiments may be practiced with various modifications and alterations.

What is claimed is:

1. A continuous time linear equalization circuit comprising:
an input of a first stage to receive a differential input signal; and
an output of the first stage to output a differential output signal,
wherein a transfer function between the input and the output exhibits two zeros and three poles in frequency domain, and
wherein the differential output signal is not fed back to the first stage.

2. A circuit according to claim 1, wherein the first stage comprises:
a first transistor, a gate of the first transistor to receive a first portion of the differential input signal;
a second transistor, a gate of the second transistor to receive a second portion of the differential input signal;
a capacitive element, a first node of the capacitive element coupled to a drain of the first transistor and a second node of the capacitive element coupled to a drain of the second transistor;
a resistive element, a first node of the resistive element coupled to the drain of the first transistor and a second node of the resistive element coupled to the drain of the second transistor;
a first current source, a first node of the first current source coupled to a supply voltage and a second node of the first current source coupled to the first node of the resistive element;
a second current source, a first node of the second current source coupled to the supply voltage and a second node of the second current source coupled to the second node of the resistive element;
a third transistor, a drain of the third transistor coupled to the supply power;
a fourth transistor, a drain of the fourth transistor coupled to the supply power;
a second resistive element, a first node of the second resistive element coupled to a gate of the third transistor and a second node of the second resistive element coupled to a source of the third transistor and to a first output node of the first stage, the first output node to output a first portion of the output differential signal; and
a third resistive element, a first node of the third resistive element coupled to a gate of the fourth transistor and a second node of the third resistive element coupled to a source of the fourth transistor and to a second output node of the first stage, the second output node to output a second portion of the output differential signal.

3. A circuit according to claim 2, further comprising:
a third current source, a first node of the third current source coupled to the supply power and a second node of the third current source coupled to the first output node; and
a fourth current source, a first node of the fourth current source coupled to the supply power and a second node of the fourth current source coupled to the second output node,
wherein at least one of the first, second and third resistive elements comprises an active transistor circuit.

4. A circuit according to claim 2, wherein the transfer function comprises:
$$\frac{{g}_{m 1}}{{g}_{m 2} ( 1 + {g}_{m 1} \frac{{R}_{s}}{2} )} \frac{( 1 + {sR}_{s} {C}_{s} ) ( 1 + {sR}_{p} {C}_{g} )}{( 1 + s \frac{{R}_{s} {C}_{s}}{( 1 + {g}_{m 1} \frac{{R}_{s}}{2} )} ) ( 1 + s \frac{{C}_{g} + {C}_{L}}{{g}_{m 2}} + {s}^{2} \frac{{R}_{p} {C}_{g} {C}_{L}}{{g}_{m 2}} )} ,$$
wherein Rₛ is a resistance of the resistive element, Rₚ is a resistance of the second and third resistive elements, gm₁ is a transconductance of the first transistor and the second transistor, gm₂ is a transconductance of the third transistor and the fourth transistor, C_{g} is a total capacitance at the gate of the third transistor and the fourth transistor, and C_{L} is a total capacitance at the output.

5. A circuit according to claim 2, wherein the second resistive element and the third resistive element each comprise a variable resistive element.

6. A circuit according to claim 5, wherein the first and second current sources comprise elements of a current mirror.

7. A circuit according to claim 5, further comprising a second stage comprising:
a fifth transistor, a gate of the fifth transistor to receive the first portion of the differential output signal;
a sixth transistor, a gate of the sixth transistor to receive the second portion of the differential output signal;
a seventh transistor, a source of the seventh transistor coupled to the supply power;
a eighth transistor, a source of the eighth transistor coupled to the supply power;
a fourth resistive element, a first node of the fourth resistive element coupled to a gate of the seventh transistor and a second node of the fourth resistive element coupled to a drain of the seventh transistor, to a source of the fifth transistor, and to a first output node of the second stage, the first output node to output a first portion of a second output differential signal; and
a fifth resistive element, a first node of the fifth resistive element coupled to a gate of the eighth transistor and a second node of the fifth resistive element coupled to a drain of the eighth transistor, to a source of the sixth transistor, and to a second output node of the second stage, the second output node to output a second portion of the second output differential signal.

8. A circuit according to claim 1, wherein the first stage comprises:
a first transistor, a gate of the first transistor to receive a first portion of the differential input signal;
a second transistor, a gate of the second transistor to receive a second portion of the differential input signal;
a capacitive element, a first node of the capacitive element coupled to a drain of the first transistor and a second node of the capacitive element coupled to a drain of the second transistor;
a resistive element, a first node of the resistive element coupled to a drain of the first transistor and a second node of the resistive element coupled to a drain of the second transistor;
a first current source, a first node of the first current source coupled to a supply voltage and a second node of the first current source coupled to the first node of the resistive element;
a second current source, a first node of the second current source coupled to the supply voltage and a second node of the second current source coupled to the second node of the resistive element;
a third transistor, a drain of the third transistor coupled to ground;
a fourth transistor, a drain of the fourth transistor coupled to ground;
a second resistive element, a first node of the second resistive element coupled to a gate of the third transistor and a second node of the second resistive element coupled to a source of the third transistor, to a source of the first transistor and to a first output node of the first stage, the first output node to output a first portion of the output differential signal; and
a third resistive element, a first node of the third resistive element coupled to a gate of the fourth transistor and a second node of the third resistive element coupled to a source of the fourth transistor, to a source of the second transistor and to a second output node of the first stage, the second output node to output a second portion of the output differential signal.

9. A circuit according to claim 8, further comprising:
a third current source, a first node of the third current source coupled to the first output node and a second node of the third current source coupled to ground; and
a fourth current source, a first node of the fourth current source coupled to the second output node and a second node of the fourth current source coupled to ground,
wherein at least one of the first, second and third resistive elements comprises an active transistor circuit.

10. A circuit according to claim 8, wherein the transfer function comprises:
$$\frac{{g}_{m 1}}{{g}_{m 2} ( 1 + {g}_{m 1} \frac{{R}_{s}}{2} )} \frac{( 1 + {sR}_{s} {C}_{s} ) ( 1 + {sR}_{p} {C}_{g} )}{( 1 + s \frac{{R}_{s} {C}_{s}}{( 1 + {g}_{m 1} \frac{{R}_{s}}{2} )} ) ( 1 + s \frac{{C}_{g} + {C}_{L}}{{g}_{m 2}} + {s}^{2} \frac{{R}_{p} {C}_{g} {C}_{L}}{{g}_{m 2}} )} ,$$
wherein Rₛ is a resistance of the resistive element, Rₚ is a resistance of the second and third resistive elements, gm₁ is a transconductance of the first transistor and the second transistor, gm₂ is a transconductance of the third transistor and the fourth transistor, C_{g} is a total capacitance at the gate of the third transistor and the fourth transistor, and C_{L} is a total capacitance at the output.

11. A circuit according to claim 8, wherein the second resistive element and the third resistive element each comprise a variable resistive element.

12. A system comprising:
a double data rate memory; and
a microprocessor in communication with the memory, wherein the microprocessor includes a continuous time linear equalization circuit comprising:
an input of a first stage to receive a differential input signal; and
an output of the first stage to output a differential output signal,
wherein a transfer function between the input and the output exhibits two zeros and three poles in frequency domain, and
wherein the differential output signal is not fed back to the first stage.

13. A system according to claim 12, wherein the first stage comprises:
a first transistor, a gate of the first transistor to receive a first portion of the differential input signal;
a second transistor, a gate of the second transistor to receive a second portion of the differential input signal;
a capacitive element, a first node of the capacitive element coupled to a drain of the first transistor and a second node of the capacitive element coupled to a drain of the second transistor;
a resistive element, a first node of the resistive element coupled to the drain of the first transistor and a second node of the resistive element coupled to the drain of the second transistor;
a first current source, a first node of the first current source coupled to a supply voltage and a second node of the first current source coupled to the first node of the resistive element;
a second current source, a first node of the second current source coupled to the supply voltage and a second node of the second current source coupled to the second node of the resistive element;
a third transistor, a drain of the third transistor coupled to the supply power;
a fourth transistor, a drain of the fourth transistor coupled to the supply power;
a second resistive element, a first node of the second resistive element coupled to a gate of the third transistor and a second node of the second resistive element coupled to a source of the third transistor and to a first output node of the first stage, the first output node to output a first portion of the output differential signal; and
a third resistive element, a first node of the third resistive element coupled to a gate of the fourth transistor and a second node of the third resistive element coupled to a source of the fourth transistor and to a second output node of the first stage, the second output node to output a second portion of the output differential signal.

14. A system according to claim 13, further comprising:
a third current source, a first node of the third current source coupled to the supply power and a second node of the third current source coupled to the first output node; and
a fourth current source, a first node of the fourth current source coupled to the supply power and a second node of the fourth current source coupled to the second output node,
wherein at least one of the first, second and third resistive elements comprises an active transistor system.

15. A system according to claim 13, wherein the transfer function comprises:
$$\frac{{g}_{m 1}}{{g}_{m 2} ( 1 + {g}_{m 1} \frac{{R}_{s}}{2} )} \frac{( 1 + {sR}_{s} {C}_{s} ) ( 1 + {sR}_{p} {C}_{g} )}{( 1 + s \frac{{R}_{s} {C}_{s}}{( 1 + {g}_{m 1} \frac{{R}_{s}}{2} )} ) ( 1 + s \frac{{C}_{g} + {C}_{L}}{{g}_{m 2}} + {s}^{2} \frac{{R}_{p} {C}_{g} {C}_{L}}{{g}_{m 2}} )} ,$$
wherein Rₛ is a resistance of the resistive element, Rₚ is a resistance of the second and third resistive elements, gm₁ is a transconductance of the first transistor and the second transistor, gm₂ is a transconductance of the third transistor and the fourth transistor, C_{g} is a total capacitance at the gate of the third transistor and the fourth transistor, and C_{L} is a total capacitance at the output.

16. A system according to claim 13, wherein the second resistive element and the third resistive element each comprise a variable resistive element.

17. A system according to claim 16, further comprising a second stage comprising:
a fifth transistor, a gate of the fifth transistor to receive the first portion of the differential output signal;
a sixth transistor, a gate of the sixth transistor to receive the second portion of the differential output signal;
a seventh transistor, a source of the seventh transistor coupled to the supply power;
a eighth transistor, a source of the eighth transistor coupled to the supply power;
a fourth resistive element, a first node of the fourth resistive element coupled to a gate of the seventh transistor and a second node of the fourth resistive element coupled to a drain of the seventh transistor, to a source of the fifth transistor, and to a first output node of the second stage, the first output node to output a first portion of a second output differential signal; and
a fifth resistive element, a first node of the fifth resistive element coupled to a gate of the eighth transistor and a second node of the fifth resistive element coupled to a drain of the eighth transistor, to a source of the sixth transistor, and to a second output node of the second stage, the second output node to output a second portion of the second output differential signal.

18. A system according to claim 12, wherein the first stage comprises:
a first transistor, a gate of the first transistor to receive a first portion of the differential input signal;
a second transistor, a gate of the second transistor to receive a second portion of the differential input signal;
a capacitive element, a first node of the capacitive element coupled to a drain of the first transistor and a second node of the capacitive element coupled to a drain of the second transistor;
a resistive element, a first node of the resistive element coupled to a drain of the first transistor and a second node of the resistive element coupled to a drain of the second transistor;
a first current source, a first node of the first current source coupled to a supply voltage and a second node of the first current source coupled to the first node of the resistive element;
a second current source, a first node of the second current source coupled to the supply voltage and a second node of the second current source coupled to the second node of the resistive element;
a third transistor, a drain of the third transistor coupled to ground;
a fourth transistor, a drain of the fourth transistor coupled to ground;
a second resistive element, a first node of the second resistive element coupled to a gate of the third transistor and a second node of the second resistive element coupled to a source of the third transistor, to a source of the first transistor and to a first output node of the first stage, the first output node to output a first portion of the output differential signal; and
a third resistive element, a first node of the third resistive element coupled to a gate of the fourth transistor and a second node of the third resistive element coupled to a source of the fourth transistor, to a source of the second transistor and to a second output node of the first stage, the second output node to output a second portion of the output differential signal.

19. A system according to claim 18, further comprising:
a third current source, a first node of the third current source coupled to the first output node and a second node of the third current source coupled to ground; and
a fourth current source, a first node of the fourth current source coupled to the second output node and a second node of the fourth current source coupled to ground,
wherein at least one of the first, second and third resistive elements comprises an active transistor system.

20. A system according to claim 18, wherein the transfer function comprises:
$$\frac{{g}_{m 1}}{{g}_{m 2} ( 1 + {g}_{m 1} \frac{{R}_{s}}{2} )} \frac{( 1 + {sR}_{s} {C}_{s} ) ( 1 + {sR}_{p} {C}_{g} )}{( 1 + s \frac{{R}_{s} {C}_{s}}{( 1 + {g}_{m 1} \frac{{R}_{s}}{2} )} ) ( 1 + s \frac{{C}_{g} + {C}_{L}}{{g}_{m 2}} + {s}^{2} \frac{{R}_{p} {C}_{g} {C}_{L}}{{g}_{m 2}} )} ,$$
wherein Rₛ is a resistance of the resistive element, Rₚ is a resistance of the second and third resistive elements, gm₁ is a transconductance of the first transistor and the second transistor, gm₂ is a transconductance of the third transistor and the fourth transistor, C_{g} is a total capacitance at the gate of the third transistor and the fourth transistor, and C_{L} is a total capacitance at the output.

21. A system according to claim 18, wherein the second resistive element and the third resistive element each comprise a variable resistive element.
